(19) United States
(12) Patent Application Publication
(10) Pub. No.: US 2002/0034938 A1
(43) Pub. Date: Mar. 21, 2002

(54) Money service apparatus in IMT-2000 network and method of the same

(76) Inventors: Chi Hyung In, Daejeon-shi (KR); Hui Il Chang, Daejeon-shi (KR); Chung Il Kim, Daejeon-shi (KR)

Correspondence Address: MERCHANT & GOULD PC, P.O. BOX 2903, MINNEAPOLIS, MN, 55402-0903, US

(21) Appl. No.: 09/740,729

(22) Filed: Dec. 19, 2000

(30) Foreign Application Priority Data
Jul. 28, 2000 (KR) 2000-43808

(51) Int. Cl. H03C 1/62; H04M 11/00

(52) U.S. Cl. 455/406; 455/433; 455/456; 455/115; 455/560

(57) ABSTRACT

The present invention relates to a money service apparatus for an IMT-2000 network and a method of the same which implements the information concerning a location of an IMT-2000 ID card and a terminal and functions for indicating the amount of money at the current rate of the foreign currency to a subscriber's own country's currency, remitting payment, making money transfer, and delivering a written notice and public notice. The money service apparatus for an IMT-2000 network includes a money service apparatus wherein the identification numbers of a terminal connected with the IMT-2000 network and a card are recognized and are provided to the subscriber, wherein a money exchange information service is provided; wherein the current location of the subscriber is searched when the subscriber requests the information on the amount of money that is converted to the local country's currency where he is located, applying the money exchange rate to his own country's currency, and then the information is provided to the termina; wherein in the case that the subscriber sets an called subscriber and requests a cash transfer to the called subscriber side, the money exchange information is searched through the money exchange information service, and the cash is provided to the called subscriber, and wherein in the case that the subscriber sets a bank account and requests a cash transfer to the bank, the money exchange rate information is searched through the money exchange information service, and the money transfer is performed to the bank.

### BACKGROUND OF THE INVENTION

1. Field of the Invention

The present invention relates to a money service apparatus in an IMT(International Mobile Telecommunication)-2000 network or the third generation telecommunication and a method of the same, and in particular to a money service apparatus for an IMT-2000 network and a method, which provides the information on the current exchange rate for a subscriber while traveling in other countries by automatically converting the foreign currency inputted by the subscriber into his or her own country's currency; which makes it possible for IMT-2000 subscribers to transmit money each other; which offers cash service or allows an entrepreneur to use a credit card using IMT-2000 terminal and an IMT-2000 ID; which helps a subscriber to pay his or her utility bills, such as an apartment maintenance fee, after being notified by SMS(Short Message Service); and which provides money transfer service.

2. Description of the Background Art

As a communication technology is advanced, various global services are locally and internationally implemented. A subscriber of an IMT-2000 terminal receives an inherent service number which is available in any region of the world.

For a bank service, a 365-banking service is available so that people can withdraw money or deposit money using the 365-banking service of the bank everyday. However, if a subscriber wants to withdraw money or deposit money using the 365-banking service, the subscriber must visit the place in person where the 365-banking service is available. Besides, the 365-banking service time is limited as well.

In addition, in the case that a subscriber travels abroad and uses a credit card, however, he faces some restriction compared to the use in his own country, especially only small amount of money is to be paid.

### SUMMARY OF THE INVENTION

Accordingly, it is an object of the present invention to provide a money service apparatus for an IMT-2000 network and a method of the same which implements information concerning a location of an IMT-2000 ID card and a terminal and functions for indicating the amount of money at the current rate of the foreign currency to a subscriber's own country's currency, remitting payment, making money transfer, and delivering a written notice and public notice.

To achieve the above objects, there is provided a money service apparatus for an IMT-2000 network which includes a money service apparatus wherein the identification numbers of a terminal connected with the IMT-2000 network and a card are recognized; wherein a money service is provided to a subscriber with money exchange rate information by searching the country where the subscriber is located in and finding the information on the current money exchange rate between the local country and his own country and displaying the result of the search on the exchange rate information in the terminal; wherein in the case that the subscriber sets a called subscriber and requests a cash transfer to the called subscriber side, the money exchange rate information is searched through the money exchange rate information service, and the cash is provided to the called subscriber; and wherein in the case that the subscriber sets a bank account and requests a cash transfer to the bank, the money exchange rate information is searched through the money exchange information service, and the money transfer is performed to the bank.

The money service apparatus includes a MSC/toll interface unit for performing an interface between a mobile switching center(MSC) and a toll switch, a service processor for controlling to provide a money service based on a subscriber location information and a money exchange rate information when a subscriber requests the service, a money exchange rate processor for controlling to provide a money exchange rate of a country in which a subscriber is currently located when the service is provided by the service processor, a location register interface unit for performing an interface so that a location information and a state information with respect to dialing subscriber or a called subscriber of a subscriber register are provided when the service processor provides a service, and a database for storing a location information, a country code, and a local time from the subscriber and a money exchange information and for providing the stored information when requested.

To achieve the above objects, there is provided a money service apparatus in a service providing apparatus for an IMT(International Mobile Telecommunication)-2000 network which includes a money service apparatus; wherein the identification numbers of a terminal and a card provided in the IMT-2000 network are recognized, and a money service is provided to a subscriber; wherein the location of the subscriber is searched when the subscriber requests to receive the information on the amount of money by converting his own country's currency to the current exchange rate of the local country he is in; wherein in the case that the subscriber sets an called subscriber and requests a cash transfer to the called subscriber, the money exchange information is searched through the money exchange information service, and the cash is transferred to the called subscriber, wherein in the case that the subscriber sets a bank and requests a cash transfer to the bank, the money exchange information is searched through the money exchange information service, and the money transfer is performed to the bank; and wherein a short message of the written notices transmitted to the subscriber is transferred to the IMT-2000 terminal of the subscriber, and the charge payment of the written notice is processed using the IMT-2000 terminal.

The money service apparatus includes a MSC/toll interface unit for controlling an interface of a mobile switching center(MSC) or a toll switch, a short message service center(SMSC) interface unit for controlling a short message transmission and receiving interface, a service processor for searching the current location of a subscriber or a service provider in accordance with a request of the money service and a money exchange rate based on the location and performing a money service function, a money exchange rate processor for providing a money exchange rate information of a country in which the subscriber is currently located when a request receives from the service processor, a location register interface unit for controlling an interface with a subscriber location register which provides a location information and a state information with respect to the dialing subscriber or called subscriber when a request receives from the service processor, and a database for saving the information on address, country code, local time and money exchange rate from the subscriber, and providing the saved information when requested.

To achieve the above objects, there is provided a money service method in a service providing method for an IMT(International Mobile Telecommunication)-2000 network for providing a money service to a subscriber whose identification numbers of a terminal connected with the IMT-2000 network and a card are recognized, which includes a first step for judging the type of a service when a message received from a subscriber corresponds to a money service message, a second step for searching the location of a subscriber when a subscriber wants the information on the amount of money that is converted to the local country's currency where he is located, applying the money exchange rate to his own country's currency, and providing a money exchange rate information service to the terminal using the money exchange of the subscriber, a third step for searching a money exchange information through the money exchange information service and providing a cash transfer service to the called subscriber in the case that a subscriber sets the called subscriber as a result of the judgment of the service type and requests a cash transfer to the called subscriber side, and a fourth step for searching a money exchange information through the money exchange information service and providing a bank money exchange service for performing a bank money transfer to the bank in the case that the subscriber sets a bank as a result of the judgment of the service type and requests a cash transfer to the bank.

To achieve the above object, there is provided a money service method in a service providing method for an IMT(International Mobile Telecommunication)-2000 network for providing a money service to a subscriber whose identification numbers connected with the IMT-2000 network, which includes a first step for judging the type of a service when a message received from a subscriber corresponds to a money service message, a second step for searching the location of the subscriber when he wants to receive the information on the amount of money that is converted to the local country's currency where he is located, applying the money exchange rate to his own country's currency, and providing a money exchange rate information service to the terminal using the money exchange of the subscriber, a third step for searching a money exchange information through the money exchange information service and providing a cash transfer service to the called subscriber in the case that a subscriber sets an called subscriber as a result of the judgment of the service type and requests a cash transfer to the called subscriber side, a fourth step for searching a money exchange information through the money exchange information service and providing a bank money exchange service for performing a bank money transfer to the bank in the case that the subscriber sets a bank as a result of the judgment of the service type and requests a cash transfer to the bank, and a fifth step for providing a money service using a short message for processing a charge payment with respect to the request content using the IMT-2000 terminal by transmitting the written notices and public notices that the subscriber currently receives to the IMT-2000 based on the short message transmission in the case that the message received from the subscriber corresponds to a service provider verification message as a result of the judgment of the step 1.

### BRIEF DESCRIPTION OF THE DRAWINGS

The present invention will become better understood with reference to the accompanying drawings which are given only by way of illustration and thus are not limitative of the present invention, wherein;

FIG. 1 is a view illustrating the construction of an IMT-2000 network including an IMT-2000 subscriber ID card and a money service apparatus according to the present invention;

FIG. 2 is a view illustrating an IMT-2000 money service apparatus of FIG. 1 according to the present invention;

FIG. 3 is a flow chart of a procedure of a service processor of FIG. 2 for a money service in an IMT-2000 network according to the present invention; and

FIG. 4 is a view illustrating a signal transfer procedure performed when an IMT-2000 network requests a money service according to the present invention.

### DETAILED DESCRIPTION OF THE PREFERRED EMBODIMENTS

The embodiments of the present invention will be explained with reference to the accompanying drawings.

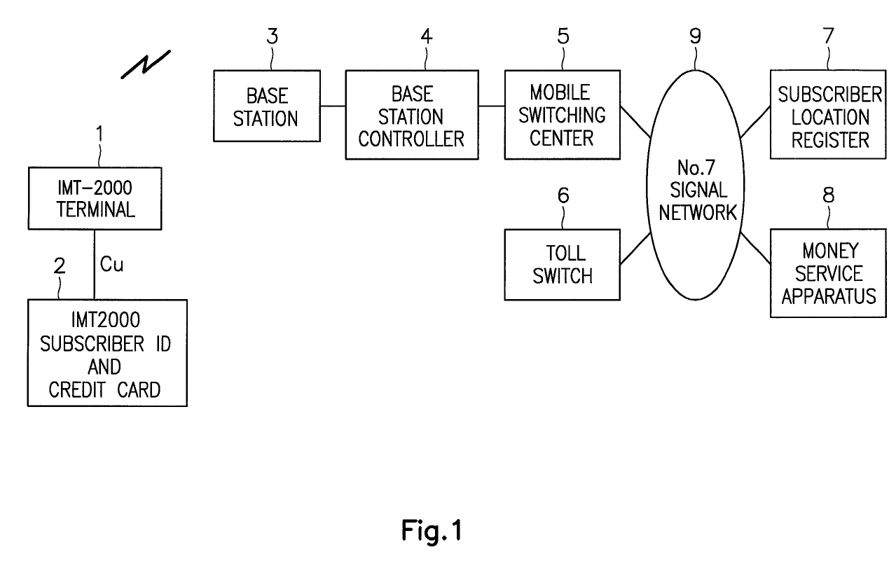

FIG. 1 is a view illustrating the construction of an IMT-2000 network including an IMT-2000 subscriber ID card and a money service apparatus according to the present invention which includes an IMT-2000 terminal 1 and a card 2, a base station 3 connected with the IMT-2000 terminal 1, a base station controller 3 for controlling the base station, a MSC(Mobile Switching Center) 4 for transmitting a signal to a base station controller in which a signal receiver subscribed when a signaler wants to signal a signal receiver in a state that a plurality of base station controllers 3 are installed, a toll switch 5 inter-working with a bank computer network, a HLR(Home Location Register) 7 for managing the current locations of the mobile terminals, an IMT-2000 money service apparatus 8 for providing a money service in accordance with a money service providing request of a user who uses the IMT-2000 terminal 1 and the card 2, and a No. 7 signal network 9 for implementing a communication between the mobile switching center 5, the tool switch 6, the subscriber location register 7 and the IMT-2000 money service apparatus 8.

At this time, the IMT-2000 money service apparatus 8 communicates with the subscriber location register 7 through the No. 7 signal network 9 for setting the current location and a signal of the mobile signal receiver when a subscriber requests a service, and the mobile switching center 5 communicates with the IMT-2000 money service apparatus 8, the toll switch 6 and the No. 7 signal network 9.

In addition, the IMT-2000 terminal 1 performs a storing function of a corresponding money by adapting an IMT-2000 subscriber identification number(ID) integrated with the credit card 2 using a Cu interface and is optionally used based on the credit card 2.

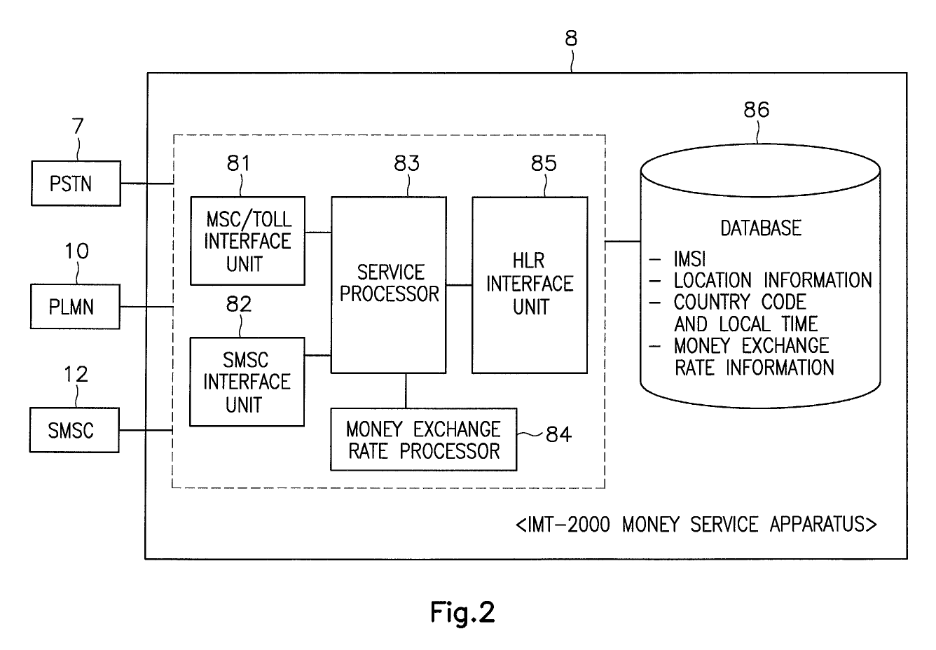

As shown in FIG. 2, the IMT-2000 money service apparatus includes a MSC/toll switch 81 for performing an interface function with the mobile switching center 5 and the tool switch 6, a SMSC(Short Message Service Center) interface unit 82 for performing an interface when a short message communication with a bank and a public office, a service processor 83 for providing a money service function based on the location and money exchange rate of a subscriber and a service company when the subscriber requests a money service, a money exchange rate processor 84 for providing a money exchange rate of a nation in which a subscriber is currently located when the service processor 83 provides a money service, a location register interface unit 85 for performing an interface with the subscriber location register 7 which provides a location information and a state information with respect to a dialing subscriber or a signal receiving subscriber when the service processor 83 provides a money service, and a database 86 for storing an identification number of the subscriber who receives the current money exchange rate and an identification number of the subscriber or an identification number of the service provider.

Here, the MSC/toll interface unit 81 receives a money service message from the dialing mobile switching center 5 through the IMT-2000 terminal 1 which requests a money service, decodes the same and transmits to the service processor 83 and receives a money service response from the service processor 26, encodes the same and transmits to the dialing mobile communication center 5.

In the case that the service type of the subscriber of the IMT-2000 terminal 1 is a money transfer service, a signal setting operation is performed with respect to the toll exchange 6 for thereby transmitting and receiving a money service message. At this time, the public mobile communication network(PLMN) 10 including the called and dialing mobile communication center 5 is connected, and the public switch telephone network(PSTN) 11 including the called toll switch 6 connected with an existing bank computer network can be connected.

When a money service provider or a public office transmits a charge requests message through the SMSC 12, the SMSC interface unit 82 receives a corresponding short message and decodes the same and requests a service provider ID and verification stored in the data base 86 and transmits to a corresponding terminal when a verified result is received based on the above request.

The service processor 83 which provides a money service to the subscriber performs a money service function based on the locations of the subscriber and service provider and provides a money service in accordance with an information stored in the database 86 when providing the service.

The money exchange rate processor 84 computes a money exchange rate of a corresponding nation at the current location of the subscriber when providing a money service from the service processor 83 to the subscriber, and the data base 86 performs a function for storing and managing an ID of a subscriber registered to the money service, a service provider ID, a location information, a nation information, a current time, and a money exchange information. Table 1 shows the stored information.

TABLE 1
Money service reference information

| Information | Parameter | Remarks |
|---|---|---|
| IMSI | Subscriber identification | |
| | number (ID) | |
| | Service provider ID | In the case of service provider |
| | Bank account number | Bank transfer |
| | IMSI money storehouse | IMT-2000 card |
| | | (setting maximum |
| | | accumulation amount when |
| | | subscribing) |
| | Max. deposit amount | Setting when registering |
| | per one time | |
| Location | Default value | Setting when registering (local |
| information | | region) |
| | Geometric information | Foreign country |
| | or cell ID or LAI | |
| | (World nation code list) | |
| Nation code | Nation code list | |
| and | Corresponding time | |
| current time | | |
| Money | Current money | Money exchange |
| exchange | exchange rate | rate compared to |
| rate | | local country |

As shown in Table 1, a subscriber ID and service provider IN are separately inputted into an IMSI(International Mobile Subscriber Identity) field. In the case that the service provider uses a bank money transfer, the one-time maximum money of the maximum accumulated money of the money storehouse(changeable) and the money transfer is stored when filling the bank account number into the IMT-2000 card.

The nation of the subscriber is set in the location information field by a default value when he subscribes. The current location with respect to the subscriber is selected among the cell ID, the location ID(Location Area Identity: LAI) and a geometric information.

A code of a country corresponding to the current location of the subscriber and an information of the current time are stored in the country code and current time field, and the current money exchange money rate based on each country code is stored in the money exchange rate field.

The location register interface unit 84 interrogates a location information and a state information of a subscriber or called subscriber through the subscriber location register 7. The location register interface unit 27 encodes an interrogation message(Any Time Interrogation) including a money service apparatus address, a request information(subscriber location and state), and a subscriber ID and transmits to the subscriber location register 7 and receives a response message(Any Time Interrogation Ack) including a location information and state of a corresponding subscriber from the subscriber location register 7 and decodes the same and provides to the service processor 83.

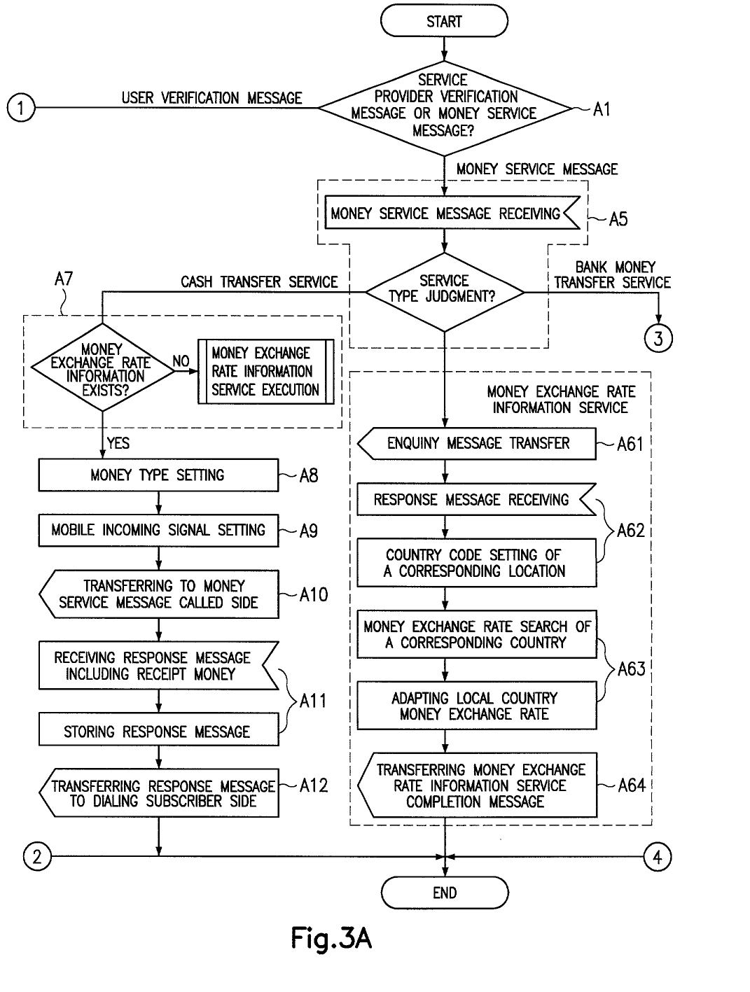

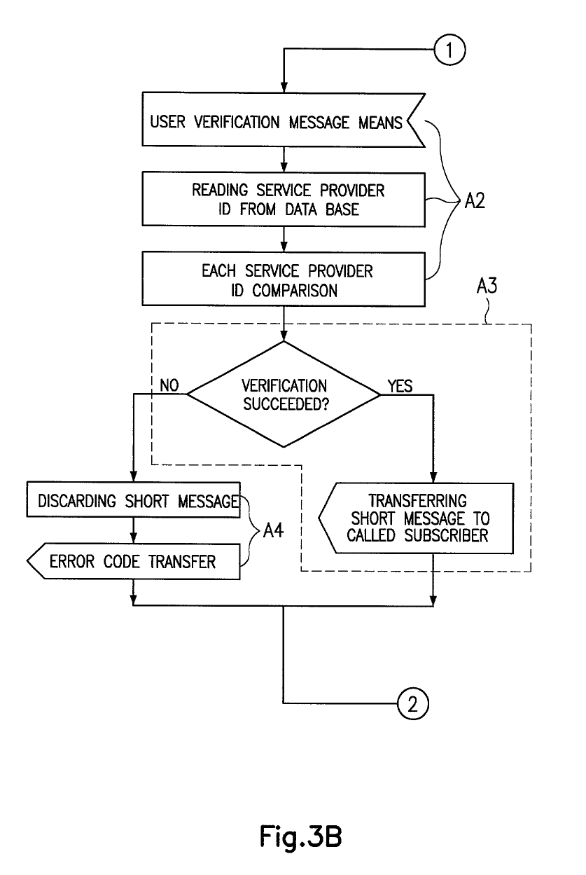

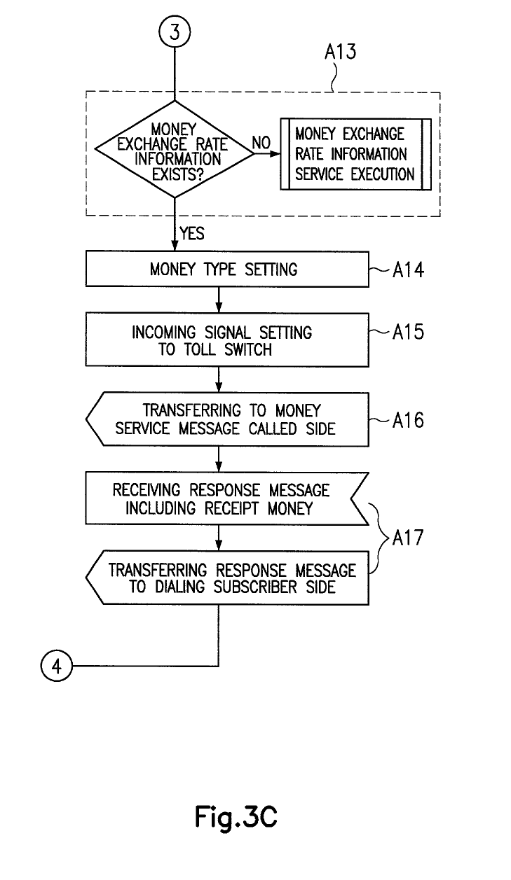

The service providing procedure of the money service apparatus will be explained with reference to FIGS. 3A to 3C.

FIGS. 3A to 3C are flow charts illustrating a procedure that the service processor 83 processes for a money service procedure in the IMT-2000 according to the present invention. In FIG. 3A, when a short message is received from a subscriber of the IMT-2000 terminal 1, it is judged whether the received short message is a message with respect to a service provider or a money service message(A1).

As a result of the judgment, if the message is a message with respect to the service provider verification, an ID with respect to the received service provider is read from the database 86 and is compared with the service provider ID included in the message for thereby performing a verification. At this time, the short message includes a charge notice message from a money service company or a bank or a public office according to the present invention(A2).

As a result of the verification, if the ID is same and the verification is succeeded, the received short message is transmitted to the called location(A3), and if failed, the received short message is discarded, and an error code which represents that the verification to the called side is failed is transmitted(A4).

As a result of the judgment of the step A1, if the short message corresponds to the money service message, the service type requested in the message is judged. At this time, the provided service includes a cash transfer service, a money exchange rate information service, a bank money transfer service, etc.(A5).

As a result of the judgment of the service type, if it is related to the money exchange rate information service, the step A6 in which the money exchange rate information is processed is performed. The location of the current subscriber is requested from the service processor 83 to the location register interface unit 85. An interrogation (AnyTimeInterrogation) message including the subscriber ID is transmitted to the location register 7 in the location register interface unit 85 based on the request(A61).

The subscriber location register 7 transmits an information including an information which represents the location of the subscriber and an information including the current state to the response message(Any Time Interrogation Act) as a response with respect to the message transmission. At this time, the location message includes a location number, a cell ID or location region ID(CellIdOrLAI), a region information(Geometric information), a location information update time(Age of Location Information), and a visit location register number(VLR number), and the subscriber information includes a busy information, a not-reachable information, and an idle information.

The location register interface unit 85 which received the response message transmits the message to the service processor 83, and the service processor 83 sets a country code of a corresponding location of the current subscriber based on the response message(A62).

When the corresponding country code is set, the money exchange rate of the current corresponding country is searched, and the money exchange rate of the subscriber's local country is adapted(A63), and the operation that the money exchange information service is being performed is informed to the subscriber, and the routine is completed(A64).

As a result of the judgment of the step A5, the service type is a cash transfer service, it is judged whether the money exchange information exists. In the case that there is not a money exchange information, the money exchange information processing procedure(A6) is performed for thereby obtaining the money exchange information(A7).

As a result of the judgment, if the money exchange ratio information exists or the money exchange information is obtained, the type of the money transferred in cash is determined among the current local money of the region in which the subscriber is currently located and the local country of the subscriber(A8).

The called mobile signal is set with respect to the called subscriber(A9), and the money service message including the money which will be transferred is transmitted to the called side(A10).

When the response message including a receipt from the called side which received the message is transmitted, the received message is stored(A11), and the money message response is transmitted to the dialing subscriber side in which the service requested, and then the routine is completed(A12).

As a result of the judgment of the step A5, if the service type is a bank money transfer service, it is judged whether the money exchange information exists. As a result of the judgment, there is not the money exchange rate information, the money exchange information processing step A6 is performed for thereby obtaining a money exchange information(A13) as in FIG. 3C.

As a result of the judgment, if there is a money exchange rate information, or the money exchange rate information is obtained, the type of the money which will be transferred in cash is determined among the current money amount of the current location in which the subscriber is currently located or the money of the local country of the subscriber(A14).

In order to perform the bank money transfer, the called procedure is performed to the toll switch 6 connected with the computer network of the bank(A15), and the money service message including the amount which will be transmitted is transmitted to the called side(A16).

When the response message including the receipt is received from the called side which received the message is transmitted, the response message is received, and the received message is transmitted to the subscriber side which requests the service as a money message response message, and the routine is completed(A17).

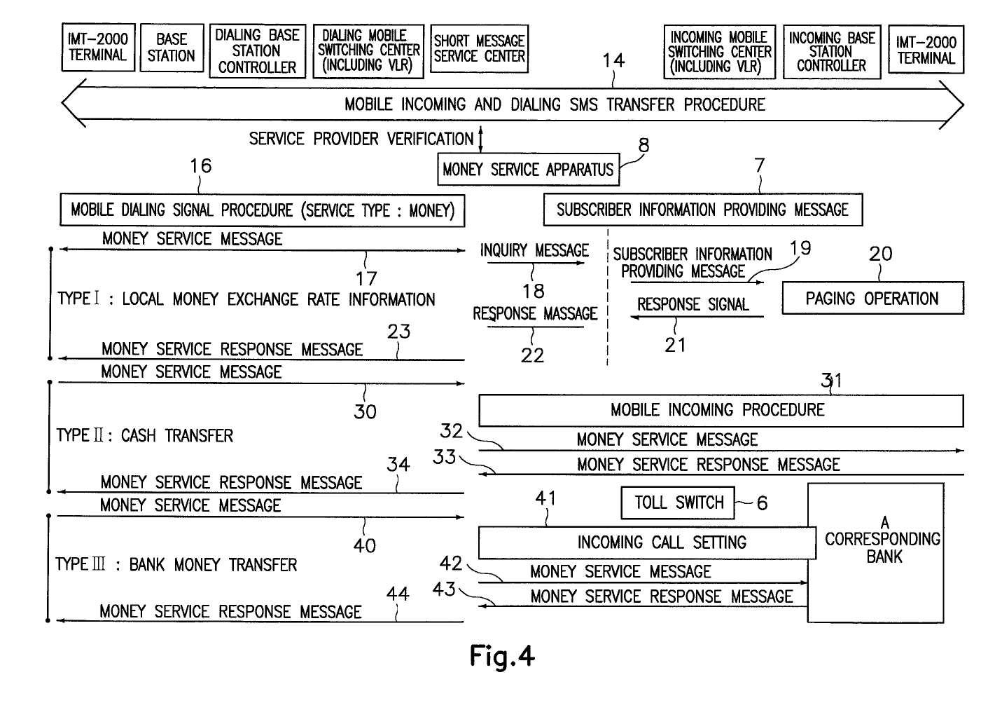

FIG. 4 is a flow chart illustrating that the service request is performed in the IMT-2000 mobile terminal according to the present invention. The mobile called and dialing short message transfer procedure 13 is used when a written notice is transmitted from the service provider or the public office using an existing short message.

The service provider verification is inquired to the money service apparatus 8. In order to implement the money service, a mobile transmission signal procedure 16 should be first implemented between the dialing side and the money service apparatus 8. At this time, the service type is defined as money. The verification and encryption procedures are identically performed.

At this time, in the case that the service type requested by the subscriber corresponds to the local money exchange information service(in the present invention, the type is defined as 1), the money service message 17 including the amount of the money is transmitted to the money service apparatus 8, and when there is a subscriber's request, an interrogation(AnyTimeInterrogation) message 18 for the location and state information of the current subscriber is transmitted to the subscriber location register 7.

The subscriber location register 7 which received the message transmits the subscriber information providing message(ProvideSubscriberInfo message) 19 and performs a paging operation and receives a response signal(ProvideSubscriberInfo) message 21.

When the paging operation is completed, the subscriber location register 7 transmits the location and state information which are a result of the paging operation with respect to a corresponding subscriber to the money service apparatus 8 based on the response message(AnyTimeInterrogationAck) 22 with respect to the interrogation message. The money service apparatus 8 exchanges the money exchange rate based on the local money type and the unit of the subscriber local country money in accordance with the location of the subscriber when the message 22 is received and transmits to the dialing subscriber through the money service response message 23.

In the case that the type of the service requested by the subscriber corresponds to the cash transfer service(in the present invention, the type is defined as 2), the money service message 30 including amount of money, a subscriber name, an called side number is transmitted to the money service apparatus 8, and the mobile arrival signal procedure 31 is performed with respect to a corresponding called side.

When the mobile arrival signal procedure is completed, the money service apparatus 8 transmits the money service message 32 to the called side and receives the money service response message 33 including a transaction date, money type, service provider name and receipt money from the called side and stores the received message into the database 86. A result of the operation is informed to the dialing side through the money service response message 34.

In the case that the service type requested by the subscriber corresponds to the bank money transfer service(in the present invention, it is defined as 3), the money service message 40 including an amount of money, money type, bank code, bank account number and subscriber name is transmitted to the money service apparatus 8. The money service apparatus 8 which received the message 40 performs(41) the called procedure based on a corresponding toll switch 6 for a connection with the bank. When the called procedure is completed, the money service message 42 is transmitted to the bank side.

When the money service response message 43 including the transaction date, money type, service provider name, and receipt amount is transmitted from the called side based on a response from the message 42, the transmitted message is received, and the money service response message 44 is reported to the dialing side.

The structures of the messages of FIGS. 3 and 4 will be explained.

TABLE 2
Money service message structure

| Information element | Existence | Length (byte) |
|---|---|---|
| Message type | M | 1 |
| Message scale | M | 1 |
| Direction Type Money type | M | 1 |
| Bank code | O | 8 |
| Bank account number (BCD) | O | 7˜9 |
| Subscriber name | O | 6˜15 |
| Receiver-side BCD number | M | 3˜43 |
| Receiver-side sub-address | O | 2˜23 |
| Amount of money | M | 1˜13 |

The message type represents the type of a money service message, and the direction classifies a message orientation and a requested amount of money and receipt.

The type represents the type of the service and indicates the bank account of a corresponding bank of the mother station of the subscriber or the local bank and account number in the case that the service provider requests a bank money transfer service,

In the personal case, the name of the subscriber is indicated. In the case of the service provider, the name of the service provider is indicated.

In addition, in the case that the money service message structure, the number of the called subscriber is included, and a sub-address may be included based on a private network of the called side.

TABLE 3
Money service response message structure

| Information element | Existence | Length (byte) |
|---|---|---|
| Message type | M | 1 |
| Message scale | M | 1 |
| Dir Type Money type | M | 1 |
| Transaction date | M | 4 |
| Service provider name | O | 6˜9 |
| Receipt amount | O | 2˜23 |
| Money exchange rate Amount | O | 1˜13 |

The message structure is a response message structure with respect to the money service request of Table 2 and includes a transaction data for performing the process based on the request, a receipt amount and the money exchange amount adapted during service.

The tables 4, 5, 6, and 7 show a detailed information on each item of Tables 2 and 3.

TABLE 4
Message type

| Bit number | Description |
|---|---|
| XX110011 | Money message REQUEST |
| XX110100 | Money message ACKNOWLEDGE |
| XX110101 | Money message REKECT |

The table 4 shows a message type of Table 2. The state that the message type which is currently transmitted is a service providing request or a response is expressed by a bit value.

| Bit number | Description |
|---|---|
| 0 | Money service request received from a |
| | mobile switching center or a |
| | money service apparatus |
| 1 | A result of a money service transmitted from a |
| | mobile switching center or |
| | a money service apparatus |

The Table 5 shows a direction of Table 2. The transmission direction is expressed by a bit value when a message is transmitted between the mobile switching center and the money service apparatus.

TABLE 6
Type

| Bit number | Description |
|---|---|
| 00 | Local money exchange rate information |
| 01 | Cash transfer |
| 10 | Bank money transfer |
| 11 | Reserved |

The Table 6 shows a field type of the Table 2. The value of the table 6 is expressed by a bit value concerning whether the service type requested by the subscriber is a certain kind.

TABLE 7
Bank code (in Korea)

| Bit number | Description |
|---|---|
| 00000000 | Reserved |
| 00000001 | Bank A |
| 00000010 | Bank B |
| 00000011 | Bank C |
| 00000100 | Bank D |
| 00000101 | Bank E |
| 00000110 | Bank F |
| . | . |
| . | . |
| . | . |
| 11111111 | Bank XX |

The Table 7 shows an example with respect to the bank code of Table 2. The bit value of each bank code at the money service providing side is defined by a bit value.

The present invention is adapted to various business types. When a service provider who operates a vending machine, a restaurant, a parking lot, a convenient store and a department store does business by adapting the IMT-2000 money service apparatus and method, the subscribers registered to the IMT-2000 service are capable of easily overcoming the problems encountered in the conventional art using the IMT-2000 money service apparatus and method according to the present invention.

As described above, in the conventional art, the mobile subscriber obtains a money exchange information by a connection with the ISP. In the present invention, the subscriber inputs a money amount(in the US, US dollar) of a foreign country using the IMT-2000 service, and the money amount of the local country of the subscriber(the won in the case of Korean) is automatically indicated. In addition, a certain amount of money is transmitted between the subscribers of the IMT-2000 service using an IMT-2000 ID card. In particular, when a service provider who operates a vending machine, a restaurant, a theater, a parking lot, a convenient store, department store, etc. and does business using the IMT-2000 money service apparatus and method according to the present invention, a quest is capable of paying using the IMT-2000 ID card, so that the service provider takes a high profit. In addition, the money exchange rate of the foreign country may be automatically adapted or may be adapted based on the subscriber's request.

When a service provider or a subscriber requests a bank money transfer to the existing bank account, the bank money transfer service is provided, so that a certain written notice made by a public office, an apartment management office, etc. is transmitted to a corresponding subscriber using the SMS. The service provider and subscriber who received the SMS pays the money using the terminal.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. In a service providing apparatus using an IMT(International Mobile Telecommunication)-2000 network, a money service apparatus in an IMT-2000 network, comprising:
a money service means:
wherein the identification numbers of a terminal connected with the IMT-2000 network and a card are recognized and are provided to a subscriber;
wherein a money exchange information service is provided wherein the location of the subscriber is searched as the subscriber requests the information on the amount of money that is converted to the local country's currency where he is located, applying the money exchange rate to his own country's currency, and then the information is provided to the terminal;
wherein in the case that the subscriber sets an called subscriber and requests a cash transfer to the called subscriber side, the money exchange information is searched through the money exchange information service, and the cash is provided to the called subscriber; and
wherein in the case that the subscriber sets a bank account and requests a cash transfer to the bank, the money exchange rate information is searched through the money exchange information service, and the money transfer is performed to the bank.

2. The apparatus of claim 1, wherein said money service means includes:
a MSC/toll interface unit for performing an interface between a mobile switching center(MSC) and a toll switch;
a service processor for controlling to provide a money service based on a subscriber location information and a money exchange rate information when a subscriber requests the service;
a money exchange rate processor for controlling to provide a money exchange rate of a country in which a subscriber is currently located when the service is provided by the service processor;
a location register interface unit for performing an interface so that a location information and a state information with respect to a dialing subscriber or an called subscriber of a subscriber register are provided when the service processor provides a service; and
a database for saving address, country code, local time and the money exchange information from the subscriber and providing the saved information when requested.

3. The apparatus of claim 2, wherein said MSC/toll interface unit receives a money service request message from the mobile switching center connected with the subscriber terminal which requests the money service, decodes the message, transmits to the service processor, receives a money service response message from the service processor, encodes the message, transmits to the mobile switching center, sets an called signal using the toll switch in the case that the service type requested by the subscriber is a bank money transfer and transmits and receives the money service message.

4. The apparatus of claim 3, wherein said money service request message includes:
a field for representing the kinds of the message;
a field for representing the scale of the message
a field for classifying a direction of the message and a request and receipt of the amount of money;
a field for classifying the types of the service;
a field for representing the type of money;
a field for classifying banks;
a field for representing a bank account number;
a field for the name of a subscriber who requested the service;
a field for representing a receiver who receives the service;
a sub address field for representing a private network of the receiver; and
a field for representing the amount of money that the receiver receives.

5. The apparatus of claim 3, wherein said money service response message includes:
a field for representing the kind of a message;
a field for representing the scale of the message;
a field for classifying the direction of the message and a request and receipt of the amount of money;
a field for classifying the types of the service;
a field for representing the kind of the money;
a field for representing the date and time when a transaction with the subscriber who requested the money service is performed;
a field for representing the name of the receiver who receives the service;
a field for certifying the receipt of the amount of money provided for the service; and
a field for representing the amount of money exchange rate adapted during the service.

6. The apparatus of claim 2, wherein said database includes:
an international mobile subscriber identification number field for classifying a subscriber identification number and a service provider identification number, storing the same and storing a bank account number when the service provider uses a bank money transfer, the maximum accumulation amount of money of the storehouse of the money set when registering to the IMT-2000 card and the one-time maximum amount of the money of the money transmission;
a location information field for setting the local country code of the subscriber when registering by the default value and storing the current location information;
a field for storing the country code provided by the service and the local time; and
a field for storing the current money exchange rate based on the country code.

7. The apparatus of claim 6, wherein a location value of the location information field is a stored value selected among a cell identification number, a location identification number(LAI) and a geometric information.

8. The apparatus of claim 2, wherein said location register interface unit inquires a location information and a state information of an called/dialing subscriber through a subscriber location register, encodes an inquiry message including an address, request information and subscriber identification number of the money service apparatus, transmits to the subscriber location register, receives the response message including a location information and a state information of a corresponding subscriber from the subscriber location register, decodes the same and provides to the service processor.

9. The apparatus of claim 1, wherein a purchase payment in a branch having an IMT-2000 money service means is implemented by an IMT-2000 card.

10. In a service providing apparatus for an IMT(International Mobile Telecommunication)-2000 network, a money service apparatus, comprising:
a money service means,
wherein the identification numbers of a terminal and a card provided in the IMT-2000 network are recognized, and a money service is provided to a subscriber;
wherein the location of the subscriber is searched when the subscriber requests to receive the information on the amount of money that is converted to the local country's currency where he is located, applying the money exchange rate to his own country's currency, and a money exchange information service of the local country is provided;
wherein in the case that the subscriber sets an called subscriber and requests a cash transfer to the called subscriber, the money exchange information is searched through the money exchange information service, and the cash is transferred to the called subscriber;
wherein in the case that the subscriber sets a bank and requests a cash transfer to the bank, the money exchange information is searched through the money exchange information service, and the money transfer is performed to the bank; and
wherein a short message of the written notices transmitted to the subscriber is transferred to the IMT-2000 terminal of the subscriber, and the charge payment of the written notice is processed using the IMT-2000 terminal.

11. The apparatus of claim 10, wherein said money service means includes:
a MSC/toll interface unit for controlling an interface of a mobile switching center(MSC) or a toll switch;
a short message service center(SMSC) interface unit for controlling a short message transmission and receiving interface;
a service processor for searching the current location of a subscriber or a service provider in accordance with a request of the money service and a money exchange rate based on the location and performing a money service function;
a money exchange rate processor for providing a money exchange rate information of a country in which the subscriber is currently located when a request is received from the service processor;
a location register interface unit for controlling an interface with a subscriber location register which provides a location information and a state information with respect to the dialing subscriber or called subscriber when a request is received from the service processor; and
a database for saving the information on address, country code, and local time from the subscriber and a money exchange information, and for providing the saved information when requested.

12. The apparatus of claim 11, wherein said MSC/toll interface unit receives a money service request message from the mobile switching center connected with the subscriber terminal which requests the money service, decodes the message, transmits to the service processor, receives a money service response message from the service processor, encodes the message, transmits to the mobile switching center, sets an called signal using the toll switch in the case that the service type requested by the subscriber is a bank money transfer and transmits and receives the money service message.

13. The apparatus of claim 12, wherein said money service request message includes:
a field for representing the kinds of the message;
a field for representing the scale of the message;
a field for classifying a direction of the message and a request and receipt of the amount of money;
a field for classifying the types of the service;
a field for representing the type of money;
a field for classifying banks;
a field for representing a bank account number;
a field for representing the name of a subscriber who requested the service;
a field for representing a receiver who receives the service;
a sub address field for representing a private network of the receiver; and
a field for representing the amount of money that the receiver receives.

14. The apparatus of claim 12, wherein said money service response message includes:
a field for representing the kind of the message;
a field for representing the scale of the message;
a field for classifying the direction of the message and a request and receipt of the amount of money;
a field for classifying the types of the service;
a field for representing the kind of the money;
a field for representing the date and time when a transaction with the subscriber who requested the money service is performed;
a field for representing the name of the receiver who receives the service;
a field for certifying the receipt of the amount of money provided for the service; and
a field for representing the amount of money exchange rate adapted during the service.

15. The apparatus of claim 11, wherein said shot message service center inquires a subscriber information registered in the database when a money service is provided through the short message, performs a verification and provides a service.

16. The apparatus of claim 11, wherein said database includes:
an international mobile subscriber identification number field for classifying a subscriber identification number and a service provider identification number, storing the same and storing a bank account number when the service provider uses a bank money transfer, the maximum accumulation amount of money of the storehouse of the money set when registering to the IMT-2000 card and the one-time maximum amount of the money of the money transmission;
a location information field for setting the local country code of the subscriber when registering by the default value and storing the current location information;
a field for storing the country code provided by the service and the local time; and
a field for storing the current money exchange rate based on the country code.

17. The apparatus of claim 16, wherein a location value of the location information field is a stored value selected among a cell identification number, a location identification number(LAI) and a geometric information.

18. The apparatus of claim 11, wherein said location register interface unit inquires a location information and a state information of an called/dialing subscriber through a subscriber location register, encodes an inquiry message including an address, request information and subscriber identification number of the money service apparatus, transmits to the subscriber location register, receives the response message including a location information and a state information of a corresponding subscriber from the subscriber location register, decodes the same and provides to the service processor.

19. The apparatus of claim 10, wherein a purchase payment in a branch having an IMT-2000 money service means is implemented by an IMT-2000 card.

20. In a service providing method for an IMT(International Mobile Telecommunication)-2000 network, a money service method for an IMT-2000 network for providing a money service to a subscriber whose identification numbers of terminal connected with the IMT-2000 network and a card are recognized comprising:
a first step for judging the type of a service when a message received from the subscriber corresponds to a money service message;
a second step for searching the location of a subscriber when a subscriber wants the information on the amount of money that is converted to the local country's currency where he is located, applying the money exchange rate to his own country's currency, and providing a money exchange rate information service to the terminal using the money exchange of the subscriber;
a third step for searching a money exchange information through the money exchange information service and providing a cash transfer service to the called subscriber in the case that the subscriber sets an called subscriber as a result of the judgment of the service type and requests a cash transfer to the called subscriber side; and
a fourth step for searching a money exchange information through the money exchange information service and providing a bank money exchange service for performing a bank money transfer to the bank in the case that the subscriber sets a bank as a result of the judgment of the service type and requests a cash transfer to the bank.

21. The method of claim 20, wherein said second step includes:
a first sub-step for requesting the location of the current subscriber who requested the service to the location register interface unit and transferring an inquiry message including the identification number of the subscriber to the subscriber location register based on the request;
a second sub-step for receiving a response message including an information which represents the location of the subscriber from the location register and a current state of the subscriber and setting a country code of a corresponding location of the current subscriber;
a third sub-step for searching a money exchange of a current corresponding country from the database when a code of a corresponding country is set and adapting to the money exchange rate of the local country of the subscriber; and
a fourth step for transferring the data adapted by the money exchange rate of the local country to the subscriber.

22. The method of claim 21, wherein in said second sub-step, the location information of the response message includes a location number, a cell identification number, a location region identification number, a region information, a location information update time, and a visit location register number information, and the subscriber state information includes a call busy information, a non-connected call information and an idle state information.

23. The method of claim 21, wherein in said third sub-step, said database is a database for storing an information of a subscriber who receives a current money exchange information and a money exchange information and includes:
an international mobile subscriber identification number field for classifying a subscriber identification number and a service provider identification number, storing the same and storing a bank account number when the service provider uses a bank money transfer, the maximum accumulation amount of money of the storehouse of the money set when registering to the IMT-2000 card and the one-time maximum amount of the money of the money transmission;
a location information field for setting the local country code of the subscriber when registering by the default value and storing the current location information;
a field for storing the country code provided by the service and the local time; and
a field for storing the current money exchange rate based on the country code.

24. The method of claim 23, wherein a location value of the location information field is a stored value selected among a cell identification number, a location identification number(LAI) and a geometric information.

25. The method of claim 20, wherein said third step includes:
a first sub-step for judging whether there is a money exchange information when the service is requested, performing a money exchange information processing step when there is not the money exchange information as a result of the judgment and obtaining the money exchange information;
a second sub-step for determining one of the money of the country in which the subscriber is currently located and the money of the local country of the subscriber with respect to the kind of the money which will be transferred in cash when there is a money exchange information or the money exchange information is obtained as a result of the judgment;
a third sub-step for setting a mobile arrival signal with respect to the called subscriber when the money is determined and transferring the money service message including the amount of the money which will be transferred to the called side;
a fourth sub-step for receiving and storing the response message when the response message including the amount of money receipt is transferred from the called side which receives the message; and
a fifth sub-step for transferring the received message to the side of the dialing subscriber who requested the service as a money message response message when the received message is stored.

26. The method of claim 20, wherein said fourth step includes:
a first sub-step for judging whether there is a money exchange information when the service is requested, performing a money exchange information processing step when there is not the money exchange information as a result of the judgment and obtaining the money exchange information;
a second sub-step for determining one of the money of the country in which the subscriber is currently located and the money of the local country of the subscriber with respect to the kind of the money which will be transferred in cash when there is a money exchange information or the money exchange information is obtained as a result of the judgment;
a third step for performing an called procedure using the toll switch connected with a computer network of the bank for performing a bank money transfer when the money is determined;
a fourth step for transferring the money service message including the amount of money which will be transferred to the called side when the called procedure is completed; and
a fifth step for receiving the response message including the amount of money receipt from the called side which received the message when the response message is transferred and transferring the received message as the money message response message to the side of the dialing subscriber who requested the service.

27. The method of claim 25, wherein said money service request message includes:
a field for representing the kinds of a message;
a field for representing the scale of the message;
a field for classifying a direction of the message and a request and receipt of the amount of money;
a field for classifying the types of the service;
a field for representing the type of money;
a field for classifying banks;
a field for representing a bank account number;
a field for the name of a subscriber who requested the service;
a field for representing a receiver who receives the service;
a sub address field for representing a private network of the receiver; and
a field for representing the amount of money that the receiver receives.

28. The method of claim 25, wherein said money service response message includes:
a field for representing the kind of a message;
a field for representing the scale of the message;
a field for classifying the direction of the message and a request and receipt of the amount of money;
a field for classifying the types of the service;
a field for representing the kind of the money;
a field for representing the date and time when a transaction with the subscriber who requested the money service is performed;
a field for representing the name of the receiver who receives the service;
a field for certifying the receipt of the amount of money provided for the service; and
a field for representing the amount of money exchange rate adapted during the service.

29. The method of claim 20, wherein a purchase payment in a branch having an IMT-2000 money service means is implemented by an IMT-2000 card.

30. In a service providing method for an IMT(International Mobile Telecommunication)-2000 network, a money service method for an IMT-2000 network for providing a money service to a subscriber whose identification numbers of a terminal connected with the IMT-2000 network and a cared are recognized, comprising:
a first step for judging the type of a service when a message received from the subscriber corresponds to a money service message;
a second step for searching the location of the subscriber when a subscriber wants the information on the amount of money that is converted to the local country's currency where he is located, applying the money exchange rate to his own country's currency, and providing a money exchange rate information service to the terminal using the money exchange of the subscriber;
a third step for searching a money exchange information through the money exchange information service and providing a cash transfer service to the called subscriber in the case that a subscriber sets the called subscriber as a result of the judgment of the service type and requests a cash transfer to the called subscriber side;
a fourth step for searching a money exchange information through the money exchange information service and providing a bank money exchange service for performing a bank money transfer to the bank in the case that the subscriber sets a bank as a result of the judgment of the service type and requests a cash transfer to the bank; and
a fifth step for providing a money service using a short message for processing a charge payment with respect to the request content using the IMT-2000 terminal by transmitting the written notices and public notices that the subscriber currently receives to the IMT-2000 based on the short message transmission in the case that the message received from the subscriber corresponds to a service provider verification message as a result of the judgment of the step 1.

31. The method of claim 30, wherein said second step includes:
a first sub-step for requesting the location of the current subscriber who requested the service to the location register interface unit and transferring an inquiry message including the identification number of the subscriber to the subscriber location register based on the request;
a second sub-step for receiving a response message including an information which represents the location of the subscriber from the location register and a current state of the subscriber and setting a country code of a corresponding location of the current subscriber;
a third sub-step for searching a money exchange of a current corresponding country from the database when a code of a corresponding country is set and adapting to the money exchange rate of the local country of the subscriber; and
a fourth step for transferring the data adapted by the money exchange rate of the local country to the subscriber.

32. The method of claim 31, wherein in said second sub-step, the location information of the response message includes a location number, a cell identification number, a location region identification number, a region information, a location information update time, and a visit location register number information, and the subscriber state information includes a call busy information, a non-connected call information and an idle state information.

33. The method of claim 23, wherein in said third sub-step, said database is a database for storing an information of a subscriber who receives a current money exchange information and a money exchange information and includes:
an international mobile subscriber identification number field for classifying a subscriber identification number and a service provider identification number, storing the same and storing a bank account number when the service provider uses a bank money transfer, the maximum accumulation amount of money of the storehouse of the money set when registering to the IMT-2000 card and the one-time maximum amount of the money of the money transmission;
a location information field for setting the local country code of the subscriber when registering by the default value and storing the current location information;
a field for storing the country code provided by the service and the local time; and
a field for storing the current money exchange rate based on the country code.

34. The method of claim 33, wherein a location value of the location information field is a stored value selected among a cell identification number, a location identification number(LAI) and a geometric information.

35. The method of claim 30, wherein said third step includes:
a first sub-step for judging whether there is a money exchange information when the service is requested, performing a money exchange information processing step when there is not the money exchange information as a result of the judgment and obtaining the money exchange information;
a second sub-step for determining one of the money of the country in which the subscriber is currently located and the money of the local country of the subscriber with respect to the kind of the money which will be transferred in cash when there is a money exchange information or the money exchange information is obtained as a result of the judgment;
a third sub-step for setting a mobile arrival signal with respect to the called subscriber when the money is determined and transferring, the money service message including the amount of the money which will be transferred to the called side;
a fourth sub-step for receiving and storing the response message when the response message including the amount of money receipt is transferred from the called side which receives the message; and
a fifth sub-step for transferring the received message to the side of the dialing subscriber who requested the service as a money message response message when the received message is stored.

36. The method of claim 30, wherein said fourth step includes:
a first sub-step for judging whether there is a money exchange information when the service is requested, performing a money exchange information processing step when there is not the money exchange information as a result of the judgment and obtaining the money exchange information;
a second sub-step for determining one of the money of the country in which the subscriber is currently located and the money of the local country of the subscriber with respect to the kind of the money which will be transferred in cash when there is a money exchange information or the money exchange information is obtained as a result of the judgment;
a third step for performing an called procedure using the toll switch connected with a computer network of the bank for performing a bank money transfer when the money is determined;
a fourth step for transferring the money service message including the amount of money which will be transferred to the called side when the called procedure is completed; and
a fifth step for receiving the response message including the amount of money receipt from the called side which received the message when the response message is transferred and transferring the received message as the money message response message to the side of the dialing subscriber who requested the service.

37. The method of claim 35, wherein said money service request message includes:
a field for representing the kinds of a message;
a field for representing the scale of the message;
a field for classifying a direction of the message and a request and receipt of the amount of money;
a field for classifying the types of the service;
a field for representing the type of money;
a field for classifying banks;
a field for representing a bank account number;
a field for the name of the subscriber who requested the service;
a field for representing a receiver who receives the service;
a sub address field for representing a private network of the receiver; and
a field for representing the amount of money that the receiver receives.

38. The method of claim 35, wherein said money service response message includes:
a field for representing the kind of the message;
a field for representing the scale of the message;
a field for classifying the direction of the message and a request and receipt of the amount of money;
a field for classifying the types of the service;
a field for representing the kind of the money;
a field for representing the date and time when a transaction with the subscriber who requested the money service is performed;
a field for representing the name of the receiver who receives the service;
a field for certifying the receipt of the amount of money provided for the service; and
a field for representing the amount of money exchange rate adapted during the service.

39. The method of claim 30, wherein said fifth step includes:
a first sub-step for reading an identification number corresponding to the received service provider from the database;
a second sub-step for comparing the identification number of the service provider included in the received message with the identification number from the database and performing a verification;
a third step for transmitting the short message to the called side when the verification is succeeded; and
a fourth step for discarding the received short message when the verification is failed and transmitting an error code which represents that the verification to the dialing side is failed.

40. The method of claim 30, wherein a purchase payment in a branch having an IMT-2000 money service means is implemented by an IMT-2000 card.
